(19) United States
(12) Patent Application Publication
(10) Pub. No.: US 2008/0017870 A1
(43) Pub. Date: Jan. 24, 2008

(54) Semiconductor light-emitting means and light-emitting panel comprising the same

(76) Inventor: Georg Diamantidis, Dernbach (DE)

Correspondence Address: FACTOR & LAKE, LTD., Suite 5G/H, 1327 W. Washington Blvd., Chicago, IL, 60607, US

(21) Appl. No.: 11/732,511

(22) Filed: Apr. 3, 2007

(30) Foreign Application Priority Data
Apr. 4, 2006 (DE) 10 2006 015 606.4

(51) Int. Cl. H01L 31/12

(52) U.S. Cl. 257/81; 257/E31.095

(57) ABSTRACT

A semiconductor light-emitting means (56) comprises a transparent substrate (12), on which light-emitting diodes (26, 28) are arranged. These and electrodes (14, 36) used for contacting them are transparent.

The invention relates to a semiconductor light-emitting means according to the precharacterising clause of Claim 1, and to a light-emitting panel comprising the same.

Semiconductor light-emitting means are known in the form of light-emitting diode means emitting light, in which the semiconductor crystals containing pn junctions are carried by opaque supports.

Semiconductor light-emitting crystals, however, radiate light coming from the recombination of electrons and holes in all directions. In the known semiconductor light-emitting means, the light radiated into the rear half-space is therefore mostly or entirely lost.

It is an object of the present invention to refine a semiconductor light-emitting means according to the precharacterising clause of Claim 1, so that the amount of useful light is increased.

This object is achieved according to the invention by a semiconductor light-emitting means having the features specified in Claim 1.

In the semiconductor light-emitting means according to the invention, the substrate carrying the luminescent semiconductor light-emitting element is transparent for the light generated by the semiconductor light-emitting element. Light radiated backwards is therefore not lost and can be used, and mirrors arranged behind the light-emitting means may optionally ensure that the light which is emitted backwards likewise reaches the front half-space.

Advantageous refinements of the invention are specified in the dependent claims.

The materials specified in Claim 2 for the substrate carrying the semiconductor light-emitting element are not only transparent but clear in their bulk, so that the substrate does not lead to any scattering of light.

The substrate specified in Claim 3 is distinguished by a particularly good hardness and good transparency in a wide wavelength range. This substrate is also particularly chemically stable and therefore also readily usable as a support in lithographic methods.

The thickness proportions specified in Claim 4 for the substrate are advantageous with a view to low weight and low costs of the substrate.

If triple layer structures are used as light sources in the semiconductor light-emitting element, as specified in Claim 5, then the electrical energy delivered to the light-emitting element is converted into light with a particularly high efficiency and the spectrum can be influenced.

In a light-emitting means according to Claim 6, the light produced in the interior of the semiconductor element can also be supplied for useful purposes. Light may also be reflected into the front half-space by mirrors placed behind the semiconductor light-emitting elements.

The refinement of the invention according to Claim 7 also makes it possible to produce spatially extended light-emitting means, and in particular two-dimensional light-emitting means.

The refinement of the invention according to Claim 8 is advantageous with a view to a high luminance. A high luminance is thereby obtained in the event that the semiconductor light-emitting elements are only partially transparent for light or are opaque, the light delivered in the forward and backward directions being used for both sets of semiconductor light-emitting elements. The fact that the semiconductor light-emitting elements of the two sets are arranged on different sides of the substrate, also has advantages with a view to good heat dissipation from the semiconductor light-emitting elements.

In a light-emitting element according to Claim 9, the substrate, together with the semiconductor light-emitting elements carried by it are substantially protected against mechanical influences from the outside.

The refinement of the invention according to Claim 10 is in this case also advantageous with a view to producing two-dimensional light-emitting means.

The refinement of the invention according to Claim 11 is advantageous with a view to good cooling of the semiconductor light-emitting elements.

According to claim 12, silicone oil in particular has proven suitable as a transparent cooling liquid. It is also distinguished by great chemical stability even at high temperatures.

A light-emitting means as specified in Claim 13 generates white light, even though the semiconductor light-emitting elements emit in UV or blue.

Claims 14 and 15 specify preferred alternatives for uniformly distributing the phosphor particles generating the white light.

For many applications, it is advantageous to have a standard light-emitting means which radiates light uniformly forwards and backwards. According to Claim 16, such a light-emitting means can be modified so that the light output overall by the semiconductor light-emitting element is radiated forwards for applications other than the standard case.

The refinement of the invention according to Claim 17 is advantageous with a view to good efficiency of the reflector part.

The refinements of the invention according to Claims 18 to 20 make it possible to operate the light-emitting means with a high operating voltage in the range of from a few 100 V to a few kV. This is advantageous for many applications in which the presence of a high voltage needs to be checked. In a light-emitting means according to one of Claims 18 to 20, no voltage divider is needed for such uses.

The refinement of the invention according to Claim 21 is in this case also advantageous with a view to generating white light with high efficiency.

A light-emitting means as specified in Claim 22 can be operated directly with a high-voltage source.

The refinements of Claims 23 to 26 are advantageous with a view to simple application of phosphor particles at intended positions.

Claim 27 specifies a light-emitting panel which can be manufactured even in very large dimensions, since the individual light-emitting means have good mechanical stability. It also exhibits good heat dissipation from the light-emitting means, and therefore also from the semiconductor light-emitting elements contained in them.

The refinement of the invention according to Claim 28 is advantageous with a view to providing light with a modified colour.

In a light-emitting panel according to Claim 29, all the light generated is delivered into the same half-space.

The refinement of the invention according to Claim 30 is advantageous with a view to good uniformity of the brightness of the light-emitting panel.

The invention will be explained in more detail below with the aid of exemplary embodiments with reference to the drawing, in which:

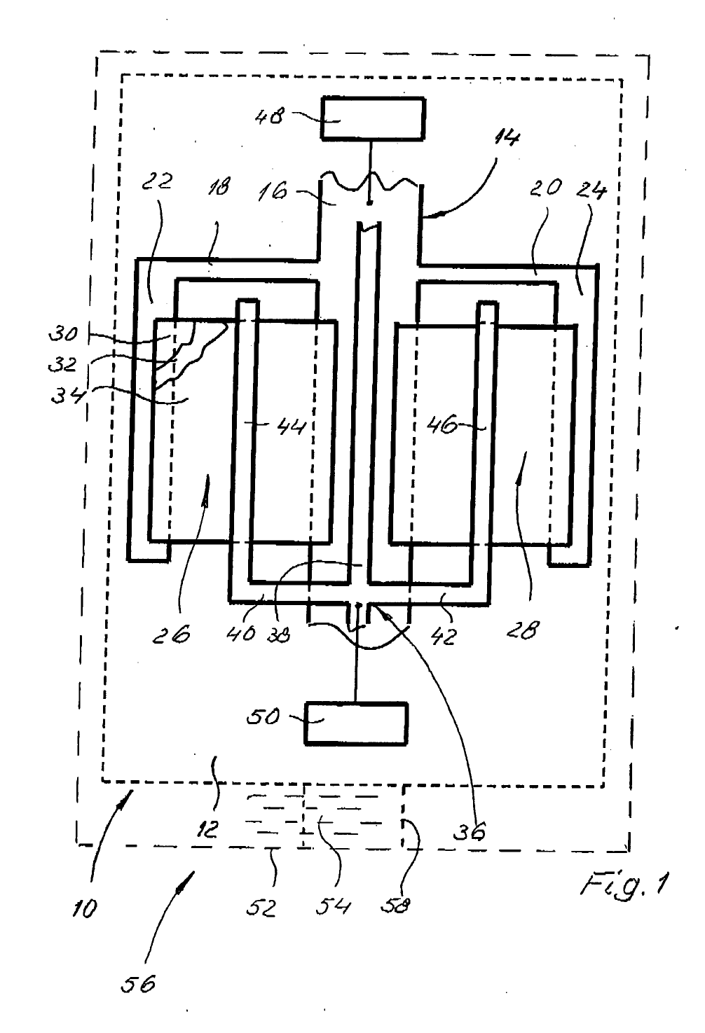

FIG. 1 shows a schematic plan view of a light-emitting element unit which, on its own or arranged together with identical units in a package, can form a light-emitting means;

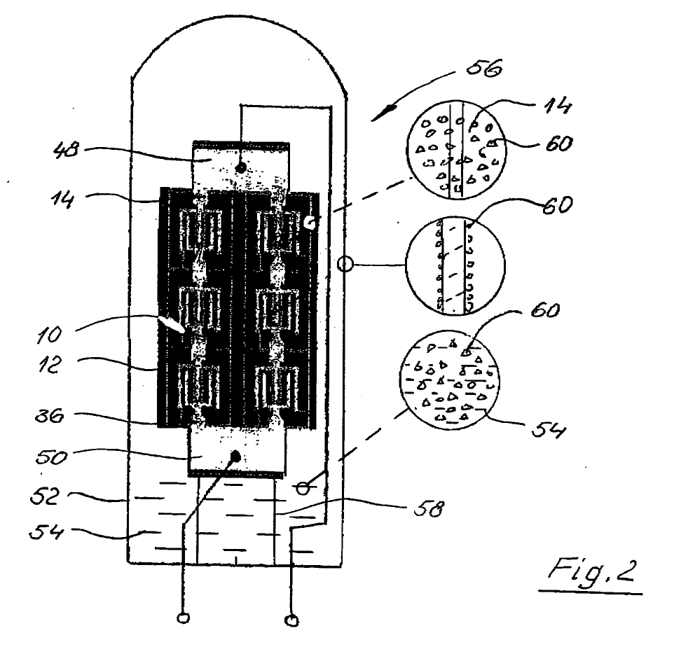

FIG. 2 shows a view of a semiconductor light-emitting means, which comprises a multiplicity of light-emitting element units according to FIG. 1;

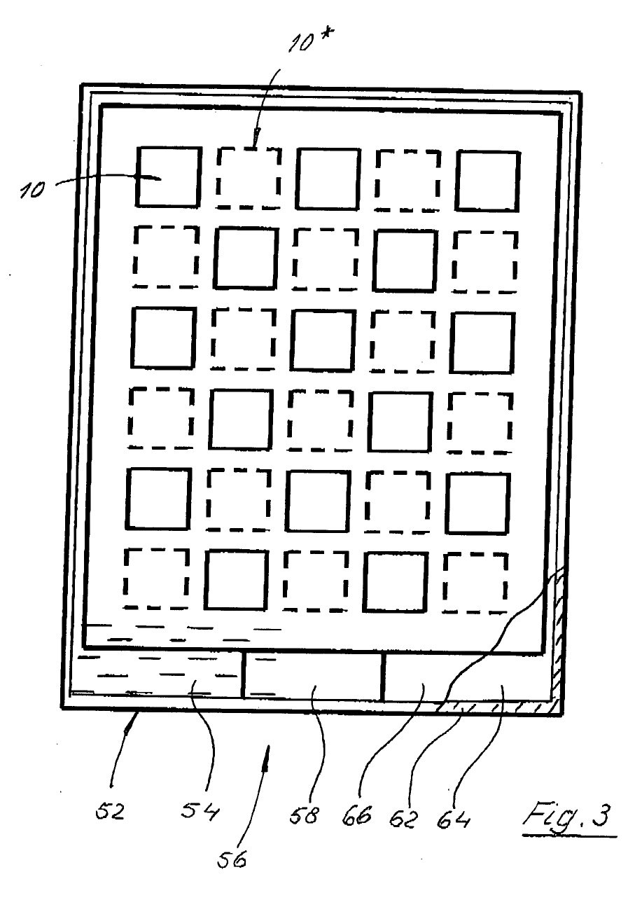

FIG. 3 shows a plan view of another semiconductor light-emitting means;

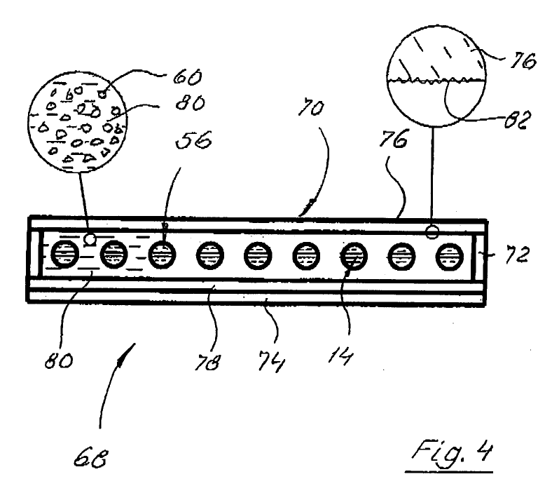

FIG. 4 shows a section through an extended, two-dimensional semiconductor light-emitting panel;

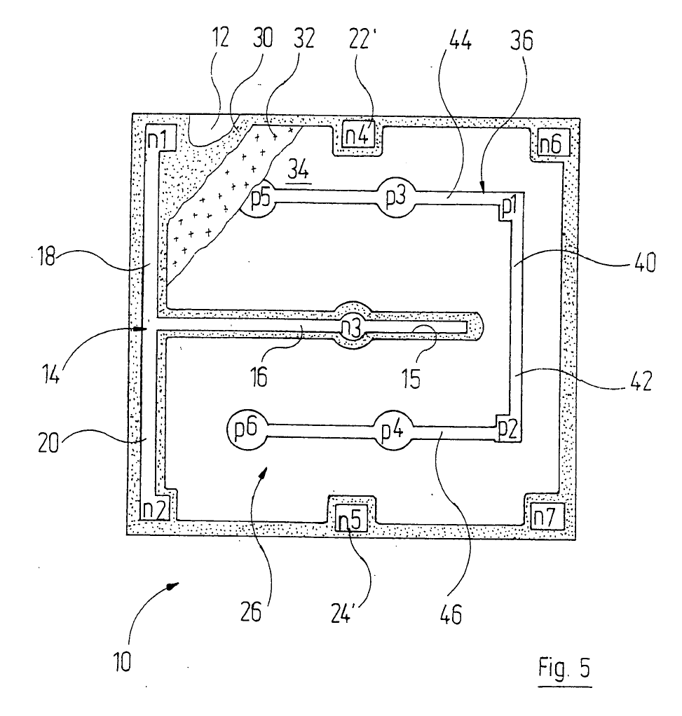

FIG. 5 shows an enlarged plan view of a light-emitting means component;

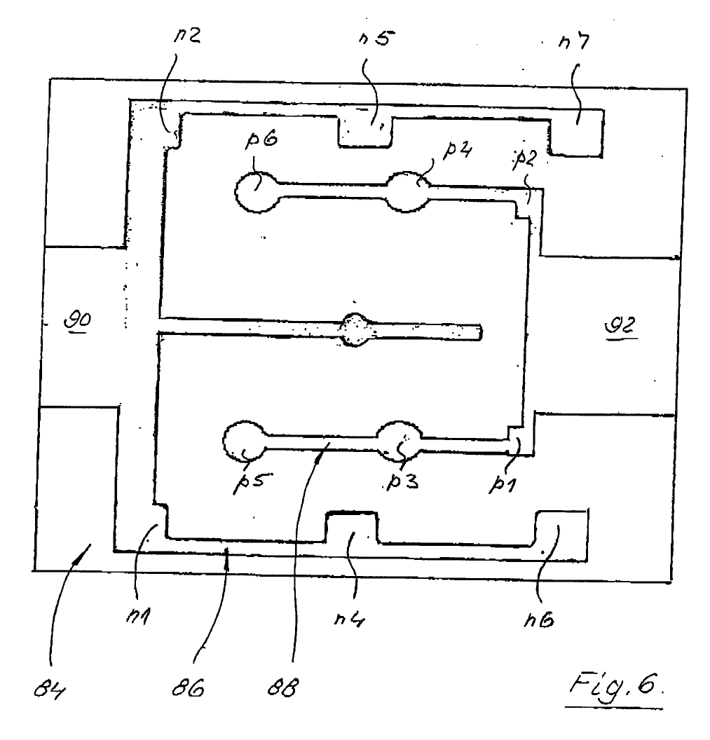

FIG. 6 shows a plan view of a light-emitting means, which is obtained by bonding the light-emitting means component of FIG. 5 onto a base substrate;

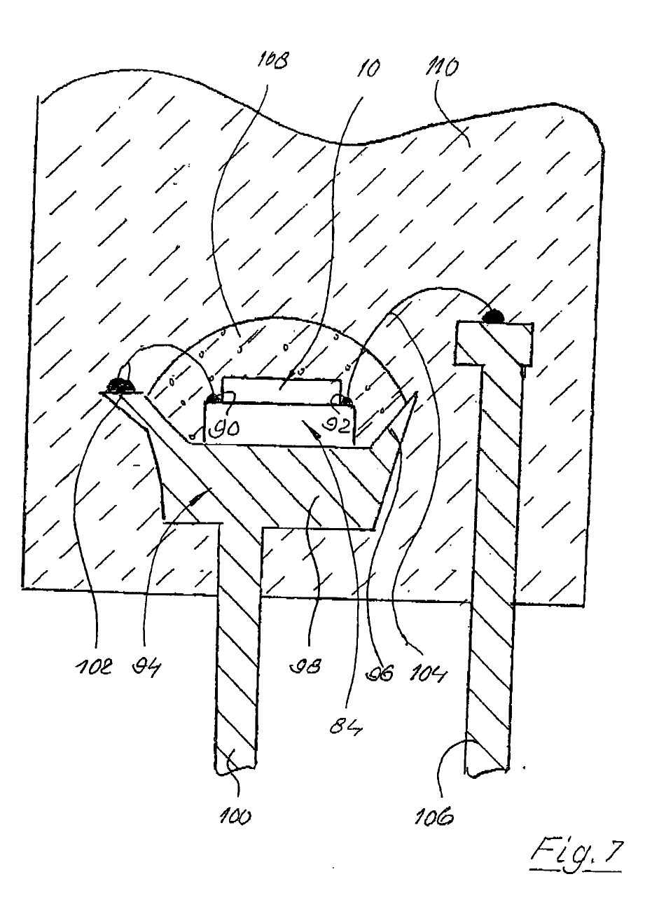

FIG. 7 shows a schematic lateral representation of a light-emitting means similar to a diode in terms of external geometry;

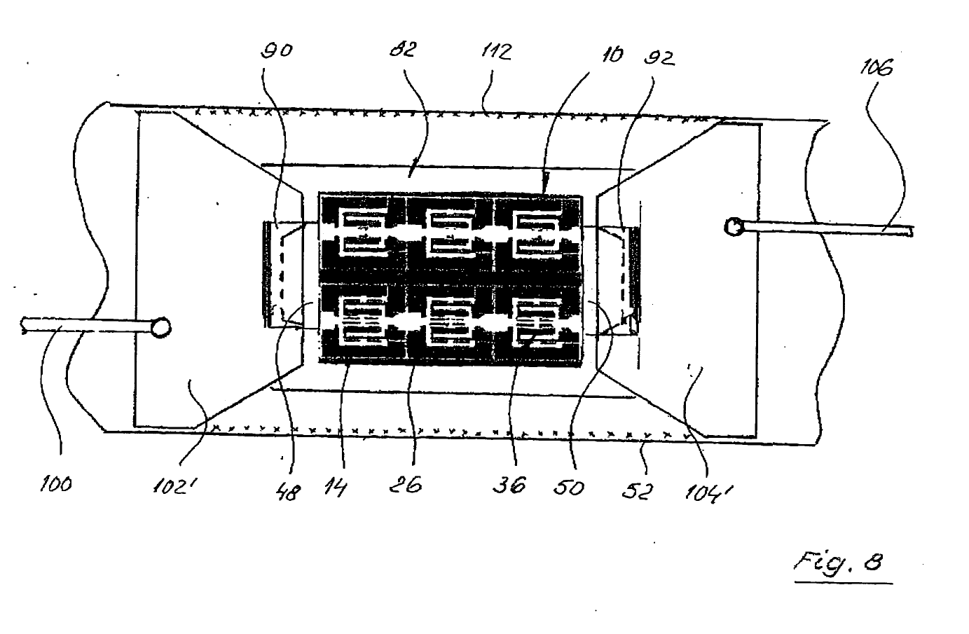

FIG. 8 shows a plan view of a modified light-emitting means, which comprises six semiconductor light-emitting elements emitting light; and

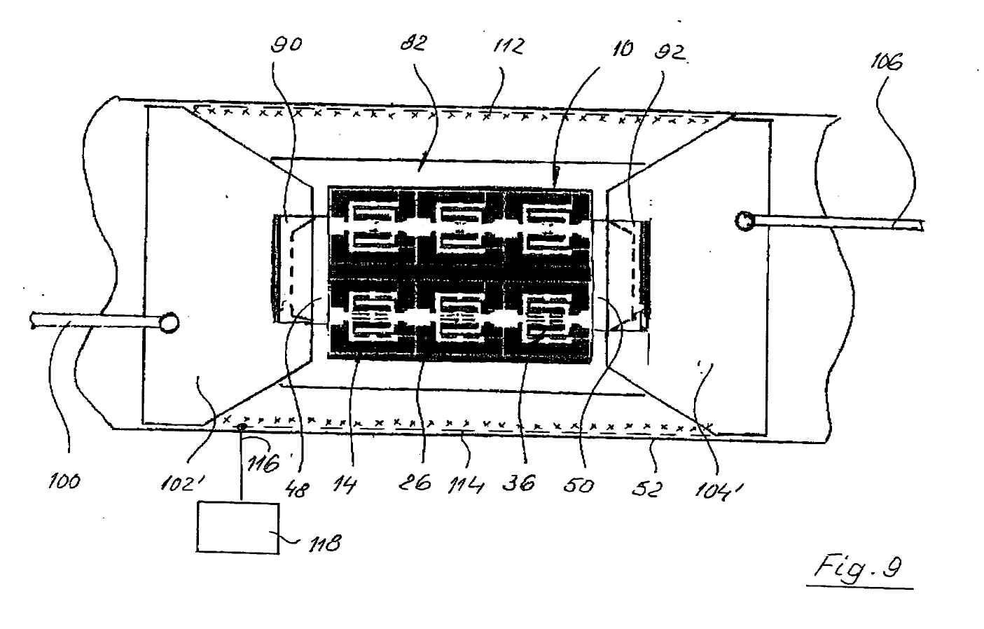

FIG. 9 shows a view similar to FIG. 8, although the light-emitting means is modified so that it radiates white light and optionally can also be operated with a high voltage.

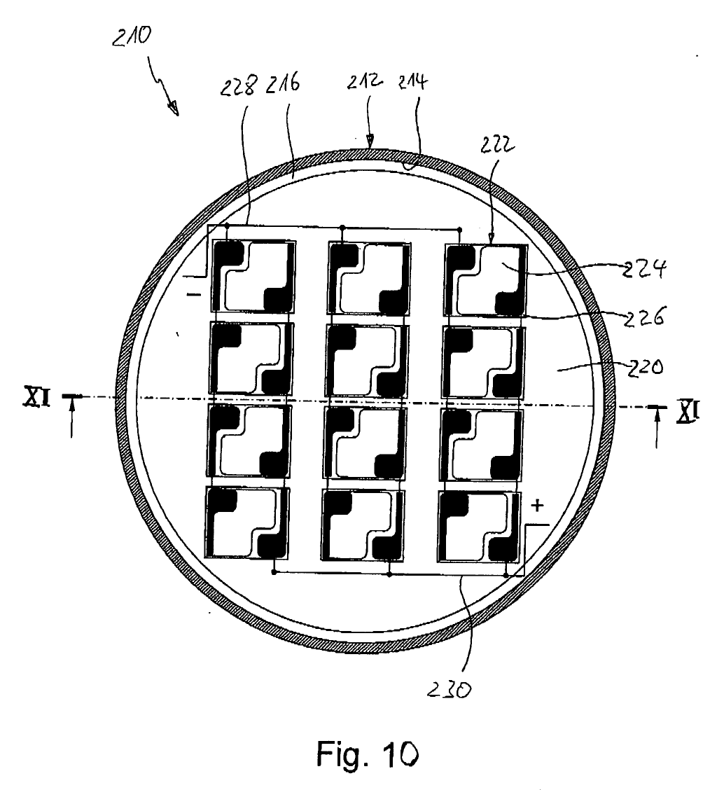

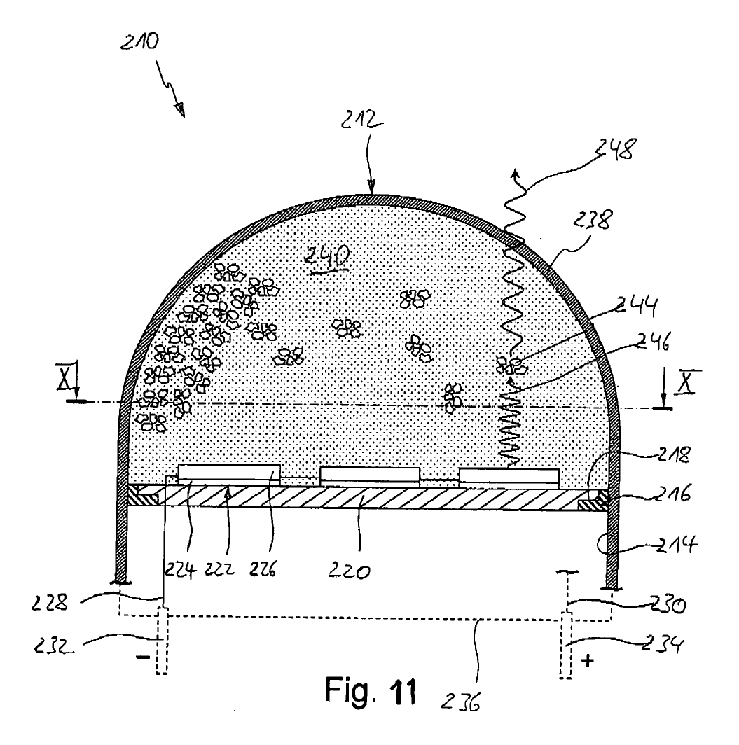

FIG. 10 shows a section through another exemplary embodiment of a light-emitting element along the section line X-X in FIG. 11;

FIG. 11 shows a section through the light-emitting element according to FIG. 10 along the section line XI-XI therein on a different scale;

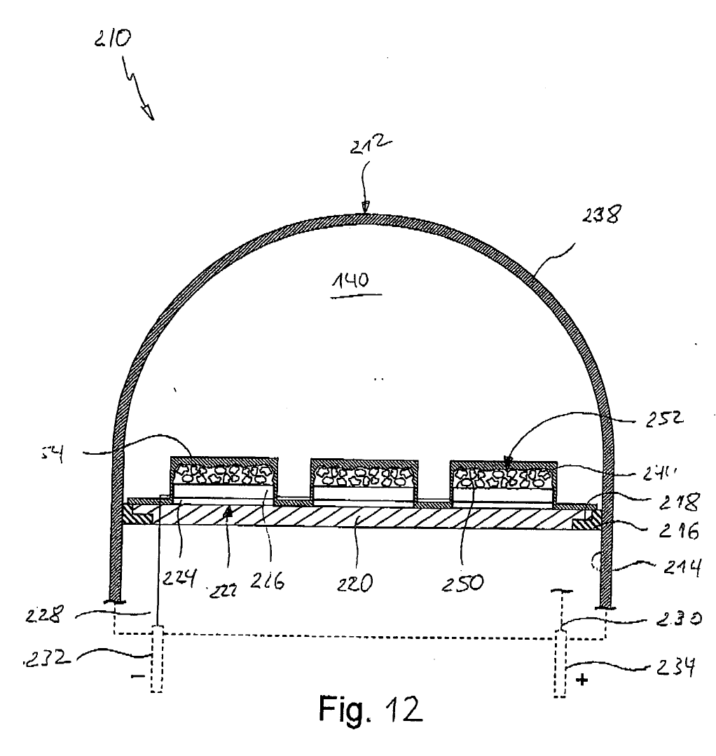

FIG. 12 shows a section corresponding to FIG. 11 through another exemplary embodiment of a light-emitting element;

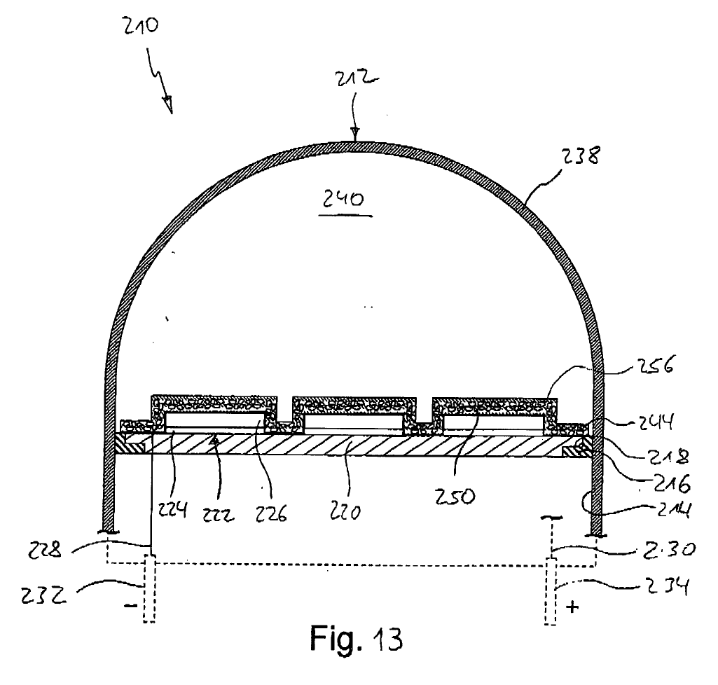

FIG. 13 shows a section corresponding to FIG. 11 through another exemplary embodiment of a light-emitting element;

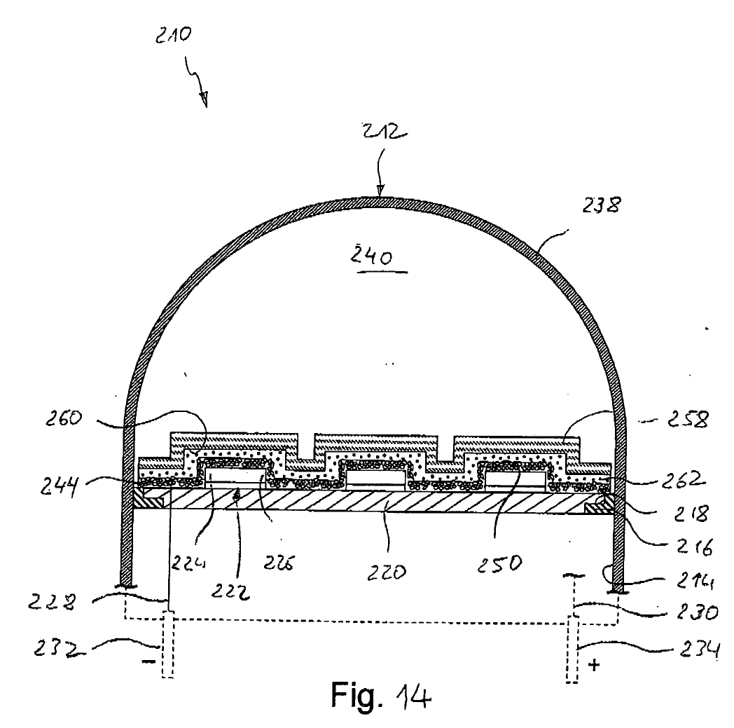

FIG. 14 shows a section corresponding to FIG. 11 through another exemplary embodiment of a light-emitting element; and

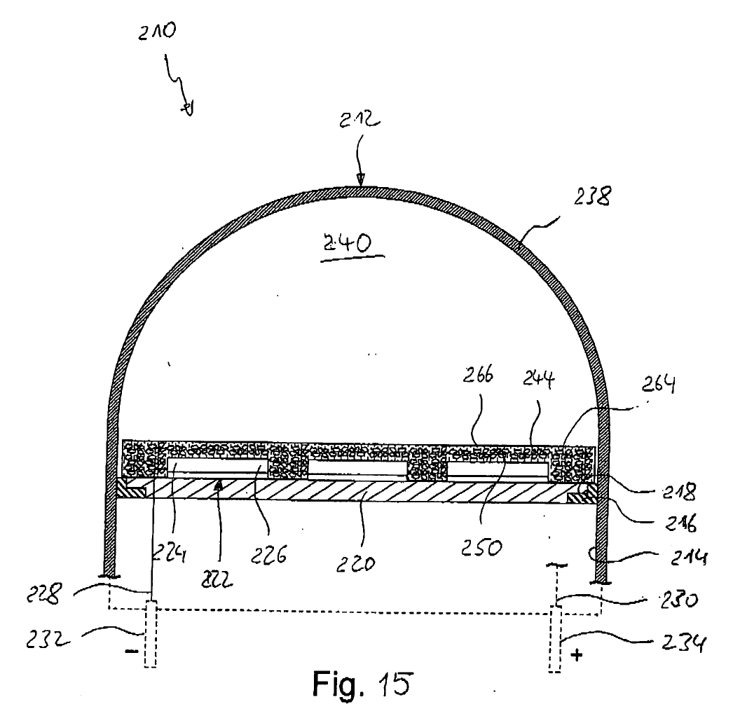

FIG. 15 shows a section corresponding to FIG. 11 through another exemplary embodiment of a light-emitting element.

In FIG. 1, 10 denotes overall a light-emitting element unit which comprises a transparent substrate 12 made from corundum glass (Al₂O₃ glass). Such glasses are also sold under the name sapphire glass. They are distinguished by a high mechanical strength, good electrical insulation properties and good thermal properties. The substrate 12 has in practice a thickness of from 300 to 400 μm.

Arranged on the upper side of the substrate 12, there is a first electrode denoted overall by 14.

It comprises a central connection conductor track 16 which, via transverse branches 18, 20, carries contact branches 22, 24 extending parallel to the connection conductor track 16.

Two two-dimensional light-emitting elements 26, 28 are placed over the connection conductor track 16 and the contact branches 22, 24, so that they overlap the latter partially in the transverse direction as can be seen from the drawing.

Each of the light-emitting elements 26, 28 comprises three layers: a lower layer 30, which contacts the connection conductor track 16 and the contact branches 22, 24 and is made of a p-type conductive III-V semiconductor material, for example InGaN.

A central layer 32 is an MQW layer. MQW is the abbreviation for multiple quantum well. An MQW material constitutes a superlattice, which has an electronic band structure modified according to the superlattice structure and correspondingly emits light at different wavelengths. The spectrum of the light output by the light-emitting elements 26, 28 can be influenced via the parameters of the MQW layer.

An upper layer 34 is an n-type conductive or intrinsically conductive layer, which may for example consist of GaN.

The three layers have overall a thickness so small that the entire triple layer structure is transparent for light.

Onto the structure described above, a second electrode 36 is vapour deposited.

It has a connection conductor track 38, which is placed over a thin oxide layer onto the structure described above and, via transverse branches 40, 42, carries contact branches 44, 46 which extend centrally over the upper layers 34 of the light-emitting elements 26, 28.

The electrodes 14, 36 are respectively connected to an upper connection plate 48 and a lower connection plate 50, which are connected under operating conditions to the terminals of a voltage source.

In this way, the light-emitting elements 26, 28 output light in the backward direction when a voltage is applied, which for the aforementioned semiconductor materials lies in the range of from 280 to 360 nm and 360 to 465 nm.

This light can leave the light-emitting element unit 10 on both sides, since the substrate 12 as well as the electrodes 14 and 36 are transparent.

In practice a light-emitting element unit 10, as has been described above, is built into a transparent package 52 which is represented only by dashes in FIG. 1.

The intermediate space between the package 52 and the light-emitting element unit 10 is filled with silicone oil 54. This liquid is used for heat dissipation from the light-emitting element unit 10. It is chemically so inert SO that it can enter into direct contact with the materials of the light-emitting element unit 10, without these being damaged thereby. Silicone oil can also be degassed very well and lastingly, and is transparent in the wavelength ranges of electromagnetic radiation of interest here.

A glass base 58 is used for mechanically joining the substrate 12 to the package 52.

The light-emitting element unit 10, together with the outer package 52 and the volume of silicone oil enclosed in it, forms a light-emitting means denoted overall by 56.

The liquid volume is shown only by way of example in a subregion of the package interior in the drawing. In actuality, it fills the package interior fully. This also applies for the other figures.

In order to increase the amount of light of the light-emitting means, a multiplicity of light-emitting element units 10, as have been explained above with reference to FIG. 1, may be combined on a common substrate. A corresponding light-emitting means 56 is represented in FIG. 2. Components which have already been explained above in a functionally equivalent form, with reference to FIG. 1, are again provided with the same reference numerals. These do not need to be described again in detail below.

It can be seen that six light-emitting element units are arranged on the substrate 12, of which three are in each case connected in series. The two sets of three light-emitting element units 10 connected in series are connected in a parallel circuit between the connection plates 48, 50.

As explained above, the light-emitting element units 10 with the said semiconductor materials radiate in ultraviolet and blue.

In order to produce a white light source by using these light-emitting element units, phosphor particles 60 which are made of a transparent solid-state material, comprising colour centres, are distributed in the silicone oil 54.

Three types of phosphor particles are employed, which respectively absorb the UV light and blue light output by the light-emitting element units 10, and emit in blue, yellow and red. The quantitative ratios between the three phosphor particles are selected so that, while taking into account a possibly differing efficiency of the light wave conversion for the various phosphor particles, white light is obtained overall from the light-emitting means 56.

As an alternative or in addition, the inner surface and/or the outer package 52 may be coated with phosphor particles 60. This may, for example, be done by coating a corresponding side of the outer package 52 with a transparent lacquer and blowing the phosphor particle mixture onto this while it is still in the tacky state.

This is likewise represented in a detail enlargement in FIG. 2.

Also as an alternative or in addition, such particle coating may also be provided for the light-emitting element unit 10, as is likewise represented in a detail enlargement in FIG. 2.

As explained above, the entire light-emitting element unit 10 is transparent (both the substrate 12 and the electrodes 14, 36 and also the light-emitting elements 26, 28). For this reason, precisely the same arrangement of electrodes and light-emitting elements is preferably also applied onto the rear side of the substrate 12. In this way, twice the amount of light is obtained for the same volume of the light-emitting means 56.

FIG. 3 also shows an extended two-dimensional light-emitting means 56, as may be used for the backlighting of displays. The light-emitting element units 10 arranged in a matrix can be seen, light-emitting element units arranged on the two sides of the substrate 12 now being mutually offset. Such an arrangement will be selected when the light-emitting element units 10 per se are not transparent.

The outer package 52 now consists of an outer frame 62 and cover plates 64, 66. These have an inner surface roughened in the manner of matt glass, in order to render the light flux uniform.

The exemplary embodiment according to FIG. 4 shows a semiconductor light-emitting panel 68. In the interior of a panel package 70 designed similarly as in FIG. 3, individual cylindrical light-emitting means 56 arranged as shown in FIG. 2, although the number of a light-emitting means' light-emitting element units 10 connected in series may be greater, for example 10 or 20 units.

The panel package 70 has a frame 72 and cover plates 74, 76, all of which are transparent. The lower cover plate 74 carries a mirror layer 78, so that all of the light generated by the light-emitting means 56 is output on one side.

The space lying between the individual light-emitting means 56 and the panel package 70 is again filled with silicone oil 80, in order to promote the heat dissipation to the surroundings. Phosphor particles 60 are again distributed in it, as described above.

A matted lower bounding surface 82 of the cover plate 76 ensures a uniform luminance of the light-emitting panel.

The exemplary embodiment according to FIG. 5 resembles that according to FIG. 1. Now, however, the contact branches 22, 24 and 44, 46 are not connected directly to current-carrying conductor tracks, as are shown in FIG. 1 at 16 and 38, rather seven connection pads n1 to n7 distributed over their length are provided. Correspondingly, the contact branches 44, 46 carry connection pads p1 to p6.

A small volume of a solder (not represented), which melts at about 350° C., is respectively applied onto the connection pads ni (i=1 to 7) and/or pi (i=1 to 6).

The contact branches are respectively in communication with the lower side and upper side of a single two-dimensional light-emitting element 26, which again consists of three layers 30, 32 and 34.

In order to be able to contact the layer 30 from the same side as the layer 34 and also gain access to the central region of the layer 30, the layer 34 comprises a central slot-shaped recess 15 in which the conductor track section 16 is accommodated with a lateral spacing.

FIG. 6 shows a plan view of a lower base plate 84, onto which the light-emitting element unit 10 of FIG. 5 can be soldered so that the upper side in FIG. 5 points downwards and contacts the upper side of the base plate 84.

The base plate 84 has a positive supply conductor track 86 and a negative supply conductor track 88. These have essentially the same geometry as the electrodes 14 and 36 and are likewise provided with connection pads n1 to n7 and p1 to p6, so that the electrodes 16, 36 are connected to the supply conductor tracks 86, 88 at a plurality of separated positions when the light-emitting means unit shown in FIG. 5 is soldered onto the base plate 84.

The supply conductor tracks 86, 88 may be applied with a substantially greater thickness onto the base plate 84 (in practice 4 to 10 times as thick) and therefore have a substantially lower resistance than the very thin electrodes 14, 36, whose thickness is in practice 10 μm to 40 μm.

The electrodes 14, 36 and the supply conductor tracks 86, 88 are obtained by vapour depositing a copper-gold alloy. As an alternative, silver or aluminium alloys may also be used.

The supply conductor tracks 86, 88 are connected to large contacts 90, 92, via which connection to the voltage source is carried out.

In a practical exemplary embodiment of the light-emitting means shown in FIGS. 5 and 6, the layer 30 of the light-emitting elements 26 consists of InGaN and the layer 34 of GaN. The middle layer 32 is again an MQW layer (multiple quantum well layer), which forms a superlattice via which the wavelength of the emitted light can be influenced.

The substrate plate 12 in the practical exemplary embodiment has an edge dimension of about 1 mm with a thickness of about 0.15 mm. The base plate 84 has edge lengths of about 1.9 mm and 1.5 mm and a plate thickness of about 0.4 mm. Both plates are cut from sapphire.

The connection pads are conventionally made from gold, which is doped for connection to a p-type conductive layer or an n-type conductive layer, respectively.

The design described above with reference to FIGS. 5 and 6 essentially permits a thoroughly transparent light source with uniform luminance.

According to FIG. 7, the light-emitting element unit 10, of which the substrate plate 12 and the base plate 84 are indicated only schematically, is arranged in the interior of a bowl-shaped reflector 94. This has a conical circumferential wall 96 tapering acutely upwards, a bottom wall 98 and a contact pin 100.

Via a wire 102, the light-emitting element unit is electrically connected to the reflector 94.

Another wire 104 connects the second connection terminal of the light-emitting element unit to another contact pin 106, which is arranged parallel at a distance from the contact pin 100.

The light-emitting element unit 10 is overlaid with a conversion material 108, which is a silicone/phosphor mixture. The phosphor material is again a mixture of different phosphor materials, which absorb the light emitted by the light-emitting element unit 10 and emit in blue, yellow and red, as described above.

The entire unit described above is embedded into a volume of transparent epoxy resin 110, which has a cylindrical basic geometry optionally with a spherical cap-shaped end surface, as is known from light-emitting elements.

FIG. 8 shows a light-emitting means which is similar to that according to FIG. 2. Comparable parts are again provided with the same reference numerals.

A difference from the light-emitting means according to FIG. 2 is that two light-emitting element units 10 are built back-to-back into the package 52 in the case of the light-emitting means according to FIG. 8.

Furthermore, the inner surface of the package 52 additionally carries a phosphor layer 112, which again constitutes a mixture of phosphor particles that absorb the light output by the light-emitting elements and emit in blue, yellow and red.

Amply dimensioned connection plates 102′ and 104′ are made from metal and are used to dissipate heat from the light-emitting elements.

The package 52 is a glass cylinder 52, which is at a vacuum of from about 2×10⁻² to 5×10⁻⁴ Torr.

A grid-shaped electrode 114 of graphite is applied onto the inner side of the glass wall of the package 52. The graphite electrode 114 is in communication with a connection 116, to which voltage can be applied from a high-voltage source 118. This may lie in the range of from 220 V to 10 kV.

The light-emitting means shown in FIG. 9 can selectively be operated with low voltage (a voltage of from about 7.5 to about 11 V being applied to the connection plates 48, 50) or with high voltage (high voltage being applied to the connection 116 and the connection plate 50 being earthed).

In order to produce white light, the inner surface of the package 52, carrying the electrode 114, may again be coated with a phosphor layer 112 as described above. The phosphor layer 112 may also fill the grid cells of the electrode 114.

In the exemplary embodiments explained with reference to FIGS. 5 to 9, the light-emitting means is produced in three substeps: production of the light-emitting element unit 10 on the sapphire substrate 12, production of the sapphire base plate 84 and the supply conductor tracks 86, 88 carried by it, and connection of the light-emitting element unit 10 and the base plate 84.

Small solder material droplets were applied onto the connection pads n1 to n7 and p1 to p6 of the substrate plate 12 and/or the base plate 84 during their production, which are then melted together in a hot method at about 350° C. under the action of pressure. After the solder has cooled, the light-emitting element unit 10 and the base plate 84 are connected both mechanically and electrically.

All the production steps for the light-emitting means can thus be carried out simply by using the known semiconductor production methods.

FIGS. 10 and 11 show sections of another light-emitting element 210. This comprises a cylindrical package 212 of transparent glass or plastic.

A holding ring 216, which comprises a radially internal shoulder 218, is flanged onto the cylindrical inner wall 214 of the package 212. A support plate 220 fastened on the holding ring 216 lies therein.

The support plate 220 is a composite system, which has layer sections of chromium, platinum and gold on its surface, and has good reflective properties.

Light-emitting chip crystals 222 arranged in a 3×4 matrix, one of which is provided with a reference numeral by way of example, are placed on the support plate 220.

The light-emitting chip crystals 222 are configured as an InGaN/GaN structure 224 on a sapphire support 226, and they are placed with the sapphire support 226 on the support plate 220.

As can be seen in FIG. 10, three chains connected in series, with four light-emitting chip crystals 222 each, are connected in parallel in the 3×4 matrix of the light-emitting chip crystals 222. The light-emitting chip crystals 222 are supplied with energy via a cathode line 228 (−) and an anode line 230 (+).

The lines 228, 230 are connected in the conventional way to connection pins 232 and 234 respectively (FIG. 2), which protrude from a fastening base 236 of the light-emitting element 210.

The fastening base 236 and the connection pins 232, 234 are conventional components, which are merely represented schematically by dashed lines in FIG. 11 for the sake of clarity.

When the light-emitting element is supplied with voltage via the connection pins 232, 234, the light-emitting chip crystals 222 begin to luminesce. The emitted wavelength is design-dependent (nature of the semiconductor material). Owing to the InGaN/GaN structures 224 used here, the light-emitting chip crystals 222 emit blue light at a wavelength of about 470 nm.

As can be seen in FIG. 11, the package 12 is closed on the opposite side from the connection base 236 by a hemispherical package end section 238, through which the generated radiation emerges from the light-emitting element 210.

Together with the support plate 220 and the holding ring 216, the package end section 238 delimits a chamber 240. The light-emitting chip crystals 222 radiate into the chamber 240, essentially parallel to the longitudinal axis of the package 212.

The chamber 240 is filled with a liquid in the form of silicone oil 242, in which a finely ground crystalline or amorphous fluorescent material 244 is dispersed homogeneously. This is indicated schematically in FIG. 11. The silicone oil 242 thus serves on the one hand as a carrier means for the fluorescent material 244, which in turn constitutes an emission medium for modifying a wavelength, and on the other hand as a cooling liquid.

As already explained above, the fluorescent material 244 comprises fluorescent particles emitting in green when exposed to blue light as well as fluorescent particles emitting in red when exposed to blue light. This is represented in FIG. 11 by the curved arrows 246 and 248, respectively. The arrow 246 represents the short-wave blue light at about 470 nm emitted from the surfaces 250 of the light-emitting chip crystals 222, whereas the curved arrow 248 represents the green or red light emitted by a fluorescent particle 244, which has a wavelength of about 580 nm or about 630 nm, respectively.

The concentration or distribution of the fluorescent material 244 in the silicone oil 242 is selected so that merely a part of the blue light of the light-emitting chip crystals 222 is absorbed by the fluorescent material 244, so that this is in turn converted only partially into green or red light. The mixture of the blue, green and red light thus leaving the light-emitting element 210 gives white light.

If it is found in practice that the white light obtained by exposure to blue light has too low a blue component in the case of one fluorescent material, then either the concentration of the fluorescent material in the silicone oil may be reduced or transparent glass or plastic particles, which do not absorb the blue light, may furthermore be added to the fluorescent material.

Owing to its good thermal conductivity, the silicone oil 242 also has a heat-dissipating effect. The working heat of the light-emitting chip crystals 222 is dissipated by the silicone oil 242 to the package wall of the package 212, and via this to the surroundings.

Instead of the InGaN/GaN structure 224, other structures which emit primary radiation of different likewise short wavelengths may also be used. If structures which emit at very short wavelengths (violet or ultraviolet) are used in this context, then another type of luminous substance, which absorbs the very short-wave primary light and fluoresces in blue, may sometimes also need to be added to the fluorescent material. It is to be understood that the luminescent substances for red and green may in this case be configured so that they absorb the violet or ultraviolet light directly. As an alternative, it would be conceivable that these luminescent substances still absorb in blue, i.e. they are excited only indirectly.

By corresponding selection of the fluorescent material 244 for such light-emitting elements, the spectrum of the radiation finally output by the light-emitting element can be adapted to the respective requirement.

FIG. 12 shows another exemplary embodiment of a light-emitting element 210, components corresponding to FIGS. 10 and 11 being denoted by the same reference numerals.

As can be seen in FIG. 12, the chamber 240 is not filled with silicone oil and dispersed fluorescent material. Rather, the fluorescent material 244 is directly applied homogeneously onto the primary-radiation emitting surface 250 of the light-emitting chip crystals 222. To this end, a coating method known per se may be employed.

To this end, it is appropriate to use finely ground fluorescent material 244, which can be applied as a powder and thus forms a surface layer 252.

This is held by means of a cover film 254 as fixing means on the radiation emitting surface 250 of the light-emitting chip crystals 222. To this end, the cover film 254 is shrunk onto the support plate 220 with the light-emitting chip crystals 222.

The cover film 254 may also be fixed in another way, for example by adhesive bonding.

The cover film 254 is transparent both for that radiation which is emitted by the light-emitting chip crystals 222, and for that radiation which is emitted by the fluorescent material 244.

Another exemplary embodiment is shown in FIG. 13, components corresponding to FIGS. 10 and 11 being denoted by the same reference numerals.

In the light-emitting element 210, a composite film 256 is provided on the light-emitting chip crystals 222 and the support plate 220 as a carrier means for the fluorescent material 244, into which the fluorescent material 244 is incorporated as a component. The composite film 256, like the cover film 254, is shrunk or adhesively bonded onto the light-emitting chip crystal 226.

In the further exemplary embodiment of a light-emitting diode 210 shown in FIG. 14, components corresponding to FIGS. 10 and 11 are denoted by the same reference numerals.

There, a fixing film 258 is provided as fixing means. It has an adhesive layer 262 on its side 260 facing the light-emitting chip crystals 222. The fluorescent material 244 is applied thereon in a homogeneous distribution, and is thereby bonded to the fixing film 258.

The layer system comprising the fixing film 258, the adhesive layer 262 and the fluorescent material 244 is shrunk or adhesively bonded onto the light-emitting chip crystals 222 and the support plate 220, so that the fluorescent material 244 faces in the direction of the light-emitting chip crystals 222.

In the exemplary embodiment of the light-emitting diode 210 shown in FIG. 15, components corresponding to FIGS. 10 and 11 are denoted by the same reference numerals.

In the light-emitting diode 210, a lacquer 264 which comprises a binder 266 is provided as a means carrying the fluorescent material 244. The binder 266 ensures that the fluorescent material 244 is distributed homogeneously in the lacquer 264.

The chambers 240 of the light-emitting diodes 210 of the exemplary embodiments according to FIGS. 12 to 15 may either be filled with an inert gas or, in order to enhance the desired effect, also filled with silicone oil in which the fluorescent material is dispersed, as in the exemplary embodiment according to FIGS. 10 and 11.

1. A semiconductor light-emitting means having at least one semiconductor light-emitting element which luminesces when a voltage is applied, and a substrate carrying the latter, wherein characterised in that the substrate and/or a liquid surrounding the semiconductor light-emitting element is transparent for the light generated by the semiconductor light-emitting elements.

2. The light-emitting means of according to claim 1, wherein the substrate comprises a glass material or a crystal material.

3. The light-emitting means of according to claim 2, wherein the glass material or the crystal material is an Al₂O₃ material.

4. The light-emitting means according to one of claim 1, wherein the substrate has a thickness of from about 0.1 mm to about 1 mm.

5. The light-emitting means of claim 1, wherein at least one semiconductor light-emitting element is a triple layer structure, the first layer being a semiconductor layer, the second layer an MQW layer, and the third layer a semiconductor layer.

6. The light-emitting means of claim 1, wherein the semiconductor light-emitting elements are transparent.

7. The light-emitting means of claim 1, wherein a multiplicity of semiconductor light-emitting elements are contacted by interdigitated electrodes.

8. The light-emitting element of claim 1, wherein the substrate carries semiconductor light-emitting elements on both sides, and in that the sets of semiconductor light-emitting elements arranged on the two sides of the substrate are mutually offset.

9. The light-emitting means of claim 1 by a package, transparent for the light generated by the semiconductor light-emitting elements, by which the substrate is carried.

10. The light-emitting means of claim 9, wherein the package encloses a multiplicity of substrates.

11. The light-emitting means of claim 9, wherein the interior of the package contains a transparent liquid.

12. The light-emitting means of claim 11, wherein the transparent liquid is a silicone oil.

13. The light-emitting means of claim 9, wherein the semiconductor light-emitting elements radiate in UV or blue and phosphor particles, which emit in blue, yellow and red, are distributed in the interior of the package so that the light-emitting means delivers white light.

14. The light-emitting means of 13, wherein the phosphor particles are applied onto the substrate and/or the semiconductor light-emitting elements and/or the inner or outer surface of the package.

15. The light-emitting means of claim 13, wherein the phosphor particles are distributed in a liquid or a solid transparent embedding material, which surrounds the substrate carrying the semiconductor light-emitting elements.

16. The light-emitting means of claim 1, further comprising a reflector part is arranged behind the semiconductor light-emitting element.

17. The light-emitting means of claim 16, wherein the reflector part is made from a crystal material, which is preferably mirrored on the rear side.

18. The light-emitting means of claims 10, wherein the inner side of the package carries a transparent electrode.

19. The light-emitting means of claim 18, wherein the electrode designed as a grid.

20. The light-emitting means of claim 19, wherein the electrode is made from graphite.

21. The light-emitting means of claim 18, wherein the electrode is overlaid with phosphor material.

22. The light-emitting means of claim 18, wherein the electrode is in communication with a connection terminal, which can be connected to a high-voltage source.

23. The light-emitting means of claim 14 further comprising a fixing film by means of which the phosphor particles are fixed on the semiconductor light-emitting element or the inner or outer surface of the package.

24. The light-emitting element of claim 23, wherein the fixing film has on one side an adhesive layer, onto which the emission medium is applied, the fixing film being applied onto the semiconductor light-emitting element so that the phosphor particle is arranged between the primary-light emitting surface of the semiconductor light-emitting element and the fixing films.

25. The light-emitting element according to claim 23, characterised in that the fixing film comprises transparent plastic.

26. The light-emitting means of claim 14, further comprising a lacquer, which is applied onto at least a part of the primary-light emitting surface of the semiconductor light-emitting element and contains phosphor particles.

27. The light-emitting panel, including a multiplicity of light-emitting means of claim 1, which are arranged in a panel package having plane-parallel cover plates, the space lying between the light-emitting means and the panel package being filled with a transparent cooling liquid.

28. The light-emitting panel of claim 27, wherein phosphor particles, which emit in blue, yellow or red, are applied onto the light-emitting means and/or the inner or outer surface of the panel package or are distributed in a cooling liquid.

29. The light-emitting panel of claim 27, wherein one of the cover plates is mirrored.

30. The light-emitting panel of claim 27, wherein one of the cover plates is designed as a matt pane.
